(19) United States
(12) Patent Application Publication
(10) Pub. No.: US 2025/0293131 A1
(43) Pub. Date: Sep. 18, 2025

(54) MODULE SUBSTRATE AND ELECTRONIC DEVICE

(71) Applicant: Murata Manufacturing Co., Ltd., Nagaokakyo-shi (JP)

(72) Inventors: Takahiro MINATOYA, Nagaokakyo-shi (JP); Shintaro HIRANO, Nagaokakyo-shi (JP); Akiyoshi MYOGADANI, Nagaokakyo-shi (JP); Koushi OKUYAMA, Nagaokakyo-shi (JP)

(73) Assignee: Murata Manufacturing Co., Ltd., Nagaokakyo-shi (JP)

(21) Appl. No.: 19/026,712

(22) Filed: Jan. 17, 2025

(30) Foreign Application Priority Data
Mar. 13, 2024 (JP) 2024-038637

(51) Int. Cl. H01L 23/498; H01L 23/66

(52) U.S. Cl. CPC H01L 23/49822; H01L 23/49838; H01L 23/49894; H01L 23/66; H01L 2223/6616; H01L 2223/6677

(57) ABSTRACT

A module substrate includes a multilayer base plate and a mounting component. The multilayer base plate includes a plurality of resin layers and a conductor layer that is provided at a predetermined one of the plurality of resin layers, and has a first surface and a second surface, which have a relationship of being a front surface and a back surface. The multilayer base plate includes an outer electrode at the first surface. Assuming a maximum height roughness of a mounting-portion-opposite region of the multilayer base plate is denoted by Rz1, a maximum height roughness of a mounting portion of the second surface of the multilayer base plate is denoted by Rz2, and a maximum height roughness of a formation region of a radiation electrode of the mounting component is denoted by Rz3, a relationship between the maximum height roughnesses is Rz1<Rz2<Rz3.

### CROSS-REFERENCE TO RELATED APPLICATION

This application claims priority to Japanese Patent Application No. JP 2024-038637 filed on Mar. 13, 2024. The entire contents of the above-identified applications, including the specifications, drawings and claims, are incorporated herein by reference in their entirety.

### BACKGROUND OF THE DISCLOSURE

### 1. Field of the Disclosure

The present disclosure relates to a module substrate that includes a multilayer base plate and a mounting component, and to an electronic device that includes the module substrate, the multilayer base plate being formed by placing resin layers upon each other, the mounting component being mounted on the multilayer base plate.

### 2. Description of the Related Art

International Publication No. 2017/051649 describes a multilayer base plate that includes a plurality of resin layers, a conductor layer that is provided at one surface of these resin layers, and an interlayer connecting conductor that is formed inside a predetermined one of the resin layers. A module substrate in which a radiation electrode is placed upon a part of the multilayer base plate is described.

### SUMMARY OF THE DISCLOSURE

Outer surfaces in a placement direction of the resin layers or the conductor layers that constitute the multilayer base plate, or a mounting surface or outer surfaces of a mounting component that is mounted on the multilayer base plate form uniform surfaces having no distinctions.

The inventor et al. of the present application have found out that, from the viewpoints of electrical characteristics and mechanical characteristics, it is important that each outer surface of the multilayer base plate or each outer surface of the module substrate that includes the multilayer base plate and the mounting component that is mounted on the multilayer base plate be a proper surface. That is, hitherto, such a notion did not exist.

For example, assuming the mounting component is to act as a single unit or as an antenna whose main portion is the mounting component, from the viewpoint of antenna characteristics, each outer surface of the mounting component is important. In addition, from the viewpoint of mechanical characteristics, it is important that a joint surface where the multilayer base plate and the mounting component are joined be a proper surface. Further, the outer surfaces of the module substrate may be required to be mounting surfaces.

Accordingly, it is an object of the present disclosure to provide a module substrate that excels in electrical characteristics and mechanical characteristics as a result of each outer surface of a multilayer base plate or an outer surface of each portion of the module substrate that includes the multilayer base plate and a mounting component being a proper surface; and to provide an electronic device that includes the module substrate.

(1) According to preferred embodiments of the present disclosure, a module substrate includes:
a multilayer base plate that includes a plurality of resin layers and a conductor layer that is provided at a predetermined one of the plurality of resin layers; and
a mounting component that includes an insulator and a radiation electrode that is formed at the insulator, the mounting component being mounted on the multilayer base plate,
in which the multilayer base plate has a first surface and a second surface, which have a relationship of being a front surface and a back surface,
in which the multilayer base plate includes an outer electrode that is exposed at the first surface,
in which the multilayer base plate includes a mounting portion at a part of the second surface of the multilayer base plate, the mounting portion being where the mounting component is mounted,
in which the mounting component has a mounting surface that contacts the mounting portion of the multilayer base plate,
in which the radiation electrode is formed at a surface away from the mounting surface or in a region along the surface,
in which the resin layer at the mounting portion of the multilayer base plate and the insulator at the mounting surface of the mounting component are directly joined to each other, and
in which assuming a maximum height roughness of a mounting-portion-opposite region of the first surface of the multilayer base plate, in which a width of the mounting-portion-opposite region is a standard length of a cross-sectional curve of the mounting-portion-opposite region, is denoted by Rz1, the mounting-portion-opposite region being a region opposite to the mounting portion,
assuming a maximum height roughness of the mounting portion of the second surface of the multilayer base plate, in which a width of the mounting portion is a standard length of a cross-sectional curve of the mounting portion, is denoted by Rz2, and
assuming a maximum height roughness of a surface of the insulator, in which a width of a formation region of the radiation electrode is a standard length of a cross-sectional curve of the insulator, is denoted by Rz3,
a relationship between the maximum height roughnesses is Rz1<Rz2<Rz3.

(2) According to preferred embodiments of the present disclosure, an electronic device includes the module substrate and another substrate on which the module substrate is mounted.

(3) According to preferred embodiments of the present disclosure, an electronic device includes the module substrate and a housing that accommodates the module substrate.

According to the present disclosure, it is possible to provide a module substrate that excels in electrical characteristics and mechanical characteristics as a result of each outer surface of the multilayer base plate or an outer surface of each portion of the module substrate that includes the multilayer base plate and the mounting component being a proper surface; and to provide an electronic component that includes the module substrate.

### BRIEF DESCRIPTION OF THE DRAWINGS

A lower portion of FIG. 1 is a sectional view of a module substrate 301 according to a first embodiment, and an upper portion of FIG. 1 is a sectional view showing a state before a mounting component 201 is mounted onto a multilayer base plate 101;

A lower portion of FIG. 2 is a sectional view of a module substrate 302 according to a second embodiment, and an upper portion of FIG. 2 is a sectional view showing a state before a mounting component 202 is mounted onto a multilayer base plate 102;

A lower portion of FIG. 3 is a sectional view of a module substrate 303 according to a third embodiment, and an upper portion of FIG. 3 is a sectional view showing a state before a mounting component 203 is mounted onto a multilayer base plate 103;

FIG. 4 is a sectional view of a module substrate 304 according to a fourth embodiment;

FIG. 5 is a sectional view of a module substrate 305 according to a fifth embodiment;

FIG. 6 is a sectional view of a module substrate 306 according to a sixth embodiment; and

FIG. 7 is a sectional view of an electronic device 407 according to a seventh embodiment.

### DESCRIPTION OF THE PREFERRED EMBODIMENTS

Embodiments for carrying out the present disclosure are described below with reference to the figures by giving several specific examples. In the figures, corresponding portions are given the same reference numerals. Considering ease of explanation or understanding of main points, modes for carrying out the disclosure are described according to embodiments. However, it is possible to partly omit, replace, or combine structures described in different embodiments. In a second embodiment and subsequent embodiments, descriptions of matters common to those of the first embodiment are omitted, and only different points are described. In particular, the same operation effects provided by corresponding structures are not mentioned one by one according to each embodiment.

### First Embodiment

In a first embodiment, a module substrate that is formed by mounting a mounting component onto a multilayer base plate is described as one example.

A lower portion of FIG. 1 is a sectional view of a module substrate 301 according to the first embodiment, and an upper portion of FIG. 1 is a sectional view showing a state before a mounting component 201 is mounted onto a multilayer base plate 101. In FIG. 1, with regard to the mounting component 201, even assuming there are a plurality of insulator layers, an interface between two insulator layers that are adjacent to each other in their layer direction is not shown. In the sectional views, lines that appear in the sections (appear by cutting) are drawn, and lines existing behind the sections are not shown. This also similarly applies to the subsequent embodiments that are described below.

The module substrate 301 includes the multilayer base plate 101 and the mounting component 201. The multilayer base plate 101 includes a plurality of resin layers 11, 12, 13, 14, and 15, and a conductor layer and an interlayer connecting conductor that are provided at a predetermined one of the resin layers.

Opening portions of the resin layer 15 are coated with connecting conductors BM. Each connecting conductor BM is made of, for example, a heating molten metal, such as solder. Pad electrodes 2a and 2b provided at the multilayer base plate are formed at lower layers of the respective connecting conductors BM. In this example, the resin layers 11, 12, 13, 14, and 15 constitute a multilayer body of thermoplastic resin sheets, one side of each having a Cu foil attached thereto.

As shown in the upper portion of FIG. 1, the multilayer base plate 101 has a first surface S1 and a second surface S2, which have a relationship of being a front surface and a back surface. A resin surface RS is exposed at the second surface S2 of the multilayer base plate 101.

At an upper surface or near the upper surface of the mounting component 201, radiation electrodes 7a and 7b and another electrode 8 are formed such that the mounting component 201 acts as a patch antenna or as a part of the patch antenna. The radiation electrodes 7a and 7b and the electrode 8 are disposed along the upper surface of the mounting component 201. In the upper portion of FIG. 1, a width Wr denotes the width of a formation region of the radiation electrodes.

Terminal electrodes 6a and 6b are formed at a mounting surface (lower surface) of the mounting component 201. A plating through hole 9 is formed between the terminal electrode 6a and the radiation electrode 7a, and a plating through hole 9 is formed between the terminal electrode 6b and the radiation electrode 7b. An insulator surface IS is exposed at the mounting surface (lower surface) of the mounting component 201. In the upper portion of FIG. 1, a width Wm is the width of a mounting portion where the mounting component 201 is mounted.

Here, a maximum height roughness of a mounting-portion-opposite region of the first surface S1 of the multilayer base plate 101, in which a width Wm of the mounting-portion-opposite region is a standard length of a cross-sectional curve of the mounting-portion-opposite region, is denoted by Rz1, with the mounting-portion-opposite region being a region opposite to the mounting portion where the mounting component 201 is mounted. Rz1 is, for example, 4 μm.

A maximum height roughness of the mounting portion, where the mounting component 201 is mounted, of the second surface S2 of the multilayer base plate 101, in which the width Wm of the mounting portion is a standard length of a cross-sectional curve of the mounting portion, is denoted by Rz2. Rz2 is, for example, 50 μm.

A maximum height roughness of a surface of an insulator of the mounting component 201, in which the width Wr of the formation region of the radiation electrodes 7a and 7b is a standard length of a cross-sectional curve of the insulator, is denoted by Rz3. Here, a “surface of an insulator surface” refers to a surface of an insulator that the radiation electrodes 7a and 7b contact.

The relationship between the maximum height roughnesses Rz1, Rz2, and Rz3 is Rz1<Rz2<Rz3. In this way, the module substrate 301 has three surfaces having different roughnesses (unevennesses).

In manufacturing the multilayer base plate 101, by pressing the resin layers that are placed upon each other with a smooth rigid body contacting the resin layers that are placed upon each other, the maximum height roughness Rz1 of the first surface S1 of the multilayer base plate 101 is determined. In addition, by pressing the second surface of the multilayer base plate 101 with an item having a low maximum height roughness contacting the second surface, the maximum height roughness Rz2 of the second surface S2 of the multilayer base plate 101 is determined.

In manufacturing the mounting component 201, by pressing the upper surface of the mounting component 201 with an item having a high maximum height roughness contacting the upper surface of the mounting component 201, the maximum height roughness Rz3 of the upper surface of the mounting component 201 is determined.

By connecting outer electrodes 1 of the multilayer base plate 101 to pad electrodes that are formed at another substrate such as that described below, the module substrate 301 is mounted on the other substrate. Alternatively, as described below, by mounting an electronic component onto the outer electrodes 1, a module substrate on which the electronic component is mounted is formed.

Signal line conductor patterns SL1 and SL2 and a ground conductor layer GL are formed inside the multilayer base plate 101. Two microstrip type transmission lines are formed by the signal line conductor patterns SL1 and SL2, the ground conductor layer GL, and the resin layers provided between the signal line conductor patterns SL1 and SL2 and the ground conductor layer GL.

As shown in FIG. 1, the mounting component 201 is placed on a predetermined position on the multilayer base plate 101, and the entire structure is heated to a predetermined temperature and is compressed by a predetermined pressure. Therefore, the connecting conductors BM are melted and the pad electrodes 2a and 2b provided at the multilayer base plate are electrically connected to the terminal electrodes 6a and 6b provided at the mounting component 201. In addition, the insulator surface IS of the mounting component 201 and the resin surface RS of the multilayer base plate 101 are directly joined to each other.

For example, the insulator material of the mounting component 201 is a material that is of the same type as the material of the resin layers 11, 12, 13, 14, and 15 of the multilayer base plate 101. Therefore, it is possible to realize high degree of contact between the mounting component 201 and the multilayer base plate 101. For example, the insulator of the mounting component 201 and the resin layers 11, 12, 13, 14, and 15 of the multilayer base plate 101 are made of thermoplastic resin, such as liquid crystal polymer resin (LCP).

Whether or not the resin materials are of the same type can be confirmed by a Fourier transform infrared spectrophotometer (FT-IR). That is, if, as a result of determining spectra by using the Fourier transform infrared spectrophotometer (FT-IR), the peaks of the spectra for the mounting component and the multilayer base plate are the same, it can be confirmed that the resin materials are of the same type.

Note that assuming the resin materials are thermoplastic resin materials, the difference between the melting points of the resin materials of the same type is small. Whether a resin portion of the multilayer base plate and a resin portion of the mounting component are made of resin materials of the same type can be confirmed by endothermic peaks of differential scanning calorimetry (DSC). Specifically, assuming, by using DSC8230 manufactured by Rigaku Corporation, the temperature of two resin materials is increased at 10° C./min, the temperature of the melted resin materials is decreased, and then the temperature of the melted resin materials is increased again at 10° C./min, a difference of 5° C. or less between the melting points of the two resin materials can be said to indicate that the two resin materials are of the same type.

Whether or not resin materials are of the same type or of different types is determined in the same way in the other embodiments that are described below.

In this way, assuming the resin materials are thermoplastic resin materials, it is possible to realize a higher degree of contact between the mounting component 201 and the multilayer base plate 101. Assuming the resin layers of the multilayer base plate 101 are made of thermoplastic resin, resin sheets can be easily placed upon each other all at once and a separate adhering step is not required, as a result of which the overall number of steps can be decreased and manufacturing costs can be decreased.

Assuming the resin layers of the multilayer base plate 101 are made of liquid crystal polymer resin, since the water absorption rate of the multilayer base plate 101 is low, variations in electrical characteristics with respect to the humidity environment are suppressed and a highly reliable module substrate can be obtained.

The insulator material of the mounting component 201 and the material of the resin layers 11, 12, 13, 14, and 15 of the multilayer base plate 101 may be of different types. For example, the material of the resin layers 11, 12, 13, 14, and 15 of the multilayer base plate 101 and the insulator material of the mounting component 201 may be such that one of the materials is thermoplastic resin and the other of the materials is thermosetting resin. Examples of the thermosetting resin include polyimide resin and epoxy resin.

The insulator of the mounting component 201 may be made of ceramic. Even in this case, the insulator surface IS of the mounting component 201 and the resin surface RS of the multilayer base plate 101 can be directly joined to each other.

Note that the resin layers of the multilayer base plate 101 need not be made of the same type of material, and may be made of different types of materials. However, assuming the resin layer 15 forming the second surface S2 is made of thermoplastic resin, the insulator surface IS of the mounting component 201 and the resin surface RS of the multilayer base plate 101 are easily directly joined to each other.

The resin layer 15 forming the second surface S2 or all of the resin layers 11 to 15 may be made of thermosetting resin. In this case, by using a sheet prior to a cross-linking reaction state for at least the resin layer 15, the sheet may be thermally hardened by heating and, during the thermal hardening, the insulator surface IS of the mounting component 201 and the resin surface RS of the multilayer base plate 101 may be directly joined to each other.

Since the mounting component 201 is a component that is provided in accordance with electrical characteristics required of an antenna, a material that provides the required characteristics can be used for the insulator material of the mounting component 201. For example, assuming it is important for the insulator of the mounting component 201 to have a high dielectric constant, a material having a dielectric constant that is higher than the dielectric constant of the resin layers of the multilayer base plate 101 is used. Therefore, it is possible to obtain the module substrate 301 including an antenna that excels in electrical characteristics.

As described above, the maximum height roughness Rz1 of the first surface S1 of the multilayer base plate 101 is lower than the maximum height roughness Rz2 of the second surface S2 of the multilayer base plate 101.

That the maximum height roughness of the first surface S1 of the multilayer base plate 101 is the lowest means that the smoothness of a mounting surface of the module substrate 301 is high. Therefore, assuming the module substrate 301 is to be mounted on another substrate, the mountability of the module substrate with respect to a highly flat mounting surface of the other substrate is high. Assuming an electronic component is to be mounted onto the outer electrodes 1 of the module substrate 301, the electronic component is highly mountable with respect to the lower surface of the highly flat module substrate 301 (the first surface S1 of the multilayer base plate 101).

As described above, the maximum height roughness Rz2 of the second surface S2 of the multilayer base plate 101 is higher than the maximum height roughness Rz1 of the first surface S1 of the multilayer base plate 101.

By causing the second surface S2 of the multilayer base plate 101 to have a predetermined maximum height roughness, the joinability of the mounting component 201 with respect to the second surface S2 of the multilayer base plate 101 is high. That is, since the actual contact area between the resin surface RS and the insulator surface IS is large, the contactability of the mounting component 201 with respect to the second surface S2 of the multilayer base plate 101 is high.

As described above, the maximum height roughness Rz3 of a surface (upper surface) of the mounting component 201 on a side opposite to the mounting surface with respect to the multilayer base plate 101 is higher than the maximum height roughness Rz1 of the first surface S1 of the multilayer base plate 101 and the maximum height roughness Rz2 of the second surface S2 of the multilayer base plate 101.

By causing the maximum height roughness of the upper surface of the mounting component to be high, compared to a mounting component where an electrode is formed at a flat surface or near the flat surface, predetermined characteristics can be set for electrical characteristics for an antenna of the mounting component. In the first embodiment, the radiation electrodes 7a and 7b and the other electrode 8 are provided at the upper surface of the mounting component 201. A patch antenna is formed by the radiation electrodes 7a and 7b, the ground conductor layer GL of the multilayer base plate 101, and the resin layers provided between the radiation electrodes 7a and 7b and the ground conductor layer GL of the multilayer base plate 101. In accordance with the maximum height roughness Rz3 of the upper surface of the mounting component 201, it is possible to set, for example, antenna directivity for a predetermined characteristic. That is, a module substrate whose mounting component excels in electrical characteristics or whose electronic circuit constituted by the mounting component and a multilayer base plate excels in electrical characteristics can be obtained.

### Second Embodiment

In the second embodiment, a module substrate whose structure for mounting a mounting component onto a multilayer base plate differs from that of the first embodiment is exemplified.

A lower portion of FIG. 2 is a sectional view of a module substrate 302 according to the second embodiment, and an upper portion of FIG. 2 is a sectional view showing a state before a mounting component 202 is mounted onto a multilayer base plate 102.

The module substrate 302 includes the multilayer base plate 102 and the mounting component 202.

The multilayer base plate 102 includes a plurality of resin layers 11, 12, 13, 14, and 15, and a conductor layer and an interlayer connecting conductor that are provided at a predetermined one of the resin layers.

An opening portion is formed in the resin layer 15 of the multilayer base plate 102, and a cavity CA is formed in a surface of a multilayer body by the opening portion. The mounting component 202 is mounted in the cavity CA of the multilayer base plate 102.

As shown in the upper portion of FIG. 2, a resin surface RS is exposed at a second surface S2 of the multilayer base plate 102. An insulator surface IS is exposed at a lower surface of the mounting component 202.

The mounting component 202 has placement-direction conductor paths formed by placing upon each other resin sheets provided with an interlayer connecting conductor 4 and a conductor foil 5 that contacts the interlayer connecting conductor 4.

Note that by forming the placement-direction conductor paths, it is possible to also form an uneven portion at an upper surface of the mounting component 202.

As in the example described in the first embodiment, assuming a maximum height roughness of a mounting portion at a first surface S1 of the multilayer base plate 102 is denoted by Rz1, a maximum height roughness of a mounting-portion-opposite region of a second surface S2 of the multilayer base plate 102 is denoted by Rz2, and a maximum height roughness of a surface of an insulator in a formation region of radiation electrodes of the mounting component 202 is denoted by Rz3, the relationship between the maximum height roughnesses is Rz1<Rz2<Rz3.

A plurality of outer electrodes 1 are exposed at the first surface S1 of the multilayer base plate 102. In the state shown in the upper portion of FIG. 2, connecting conductors BM that are each conductive with respect to an end portion of a corresponding one of signal line conductor patterns SL1 and SL2 are formed at the second surface (surface in the cavity CA) of the multilayer base plate 102.

The mounting component 202 is a multilayer base plate in which resin layers are placed upon each other, and the resin material of each resin layer of the mounting component 202 and the resin material of each resin layer of the multilayer base plate 102 are of the same type. The materials are, for example, thermoplastic resin. An example of the thermoplastic resin is liquid crystal polymer resin (LCP).

As shown in FIG. 2, by mounting the mounting component 202 into the cavity CA of the multilayer base plate 102 and compressing and heating the entire structure until a predetermined temperature is reached, the mounting component 202 is adhered to and mounted in the cavity CA of the multilayer base plate 102. That is, the end portions of the respective signal line conductor patterns SL1 and SL2 that are provided at the multilayer base plate are electrically connected to terminal electrodes 6a and 6b provided at the mounting component 202 via the connecting conductors BM. In addition, the insulator surface IS of the mounting component 202 and the resin surface RS of the multilayer base plate 102 are directly joined to each other.

Note that the resin layers of the mounting component 202 need not be made of the same type of material, and may be made of different types of materials. Similarly, the resin layers of the multilayer base plate 102 need not be made of the same type of material, and may be made of different types of materials.

### Third Embodiment

In a third embodiment, a method of joining a material of an insulator of a mounting component and a material of a multilayer base plate is further exemplified.

A lower portion of FIG. 3 is a sectional view of a module substrate 303 according to the third embodiment, and an upper portion of FIG. 3 is a sectional view showing a state before a mounting component 203 is mounted onto a multilayer base plate 101.

The module substrate 303 includes the multilayer base plate 101 and the mounting component 203. The mounting component 203 is mounted on a second surface S2 of the multilayer base plate 101.

The multilayer base plate 101 is the same as the multilayer base plate 101 in the first embodiment.

As in the example described in the first embodiment, assuming a maximum height roughness of a mounting portion at a first surface S1 of the multilayer base plate 101 is denoted by Rz1, a maximum height roughness of a mounting-portion-opposite region of a second surface S2 of the multilayer base plate 101 is denoted by Rz2, and a maximum height roughness of a surface of the insulator in a formation region of radiation electrodes of the mounting component 203 is denoted by Rz3, the relationship between the maximum height roughnesses is Rz1<Rz2<Rz3.

The mounting component 203 is a multilayer base plate in which resin layers are placed upon each other, and the resin material of each resin layer of the mounting component 203 and the resin material of each resin layer of the multilayer base plate 101 are of different types. For example, each resin layer of the mounting component 203 is made of thermosetting resin, such as polyimide resin or epoxy resin, and each resin layer of the multilayer base plate 101 is made of thermoplastic resin, such as liquid crystal polymer resin. Alternatively, for example, each resin layer of the multilayer base plate 101 is made of thermosetting resin, such as polyimide resin or epoxy resin, and each resin layer of the mounting component 203 is made of thermoplastic resin, such as liquid crystal polymer resin.

As shown in FIG. 3, by mounting the mounting component 203 onto an upper surface of the multilayer base plate 101 and by compressing and heating the entire structure, the mounting component 203 is adhered to and mounted on the upper surface of the multilayer base plate 101. That is, pad electrodes 2a and 2b provided at the multilayer base plate are electrically connected to terminal electrodes 6a and 6b provided at the mounting component 203. In addition, an insulator surface IS of the mounting component 203 and a resin surface RS of the multilayer base plate 101 are directly joined to each other.

Note that the resin layers of the multilayer base plate 101 need not be made of the same type of material, and may be made of different types of materials. In addition, resin sheets of the mounting component 203 need not be made of the same type of material, and may be made of different types of materials. However, assuming a resin layer 15 forming the second surface S2 and/or a resin layer provided at a mounting surface of the mounting component 203 is made of thermoplastic resin, the insulator surface IS of the mounting component 201 and the resin surface RS of the multilayer base plate 101 are easily directly joined to each other.

The resin layer 15 forming the second surface S2 and the resin layer provided at the mounting surface of the mounting component 203 may be made of thermosetting resin. In this case, by using a sheet prior to a cross-linking reaction state for the resin layer 15 forming the second surface S2 and/or for the resin layer provided at the mounting surface of the mounting component 203, the sheet may be thermally hardened by heating and, during the thermal hardening, the insulator surface IS of the mounting component 203 and the resin surface RS of the multilayer base plate 101 may be directly joined to each other.

### Fourth Embodiment

In a fourth embodiment, a module substrate including an electronic component is exemplified.

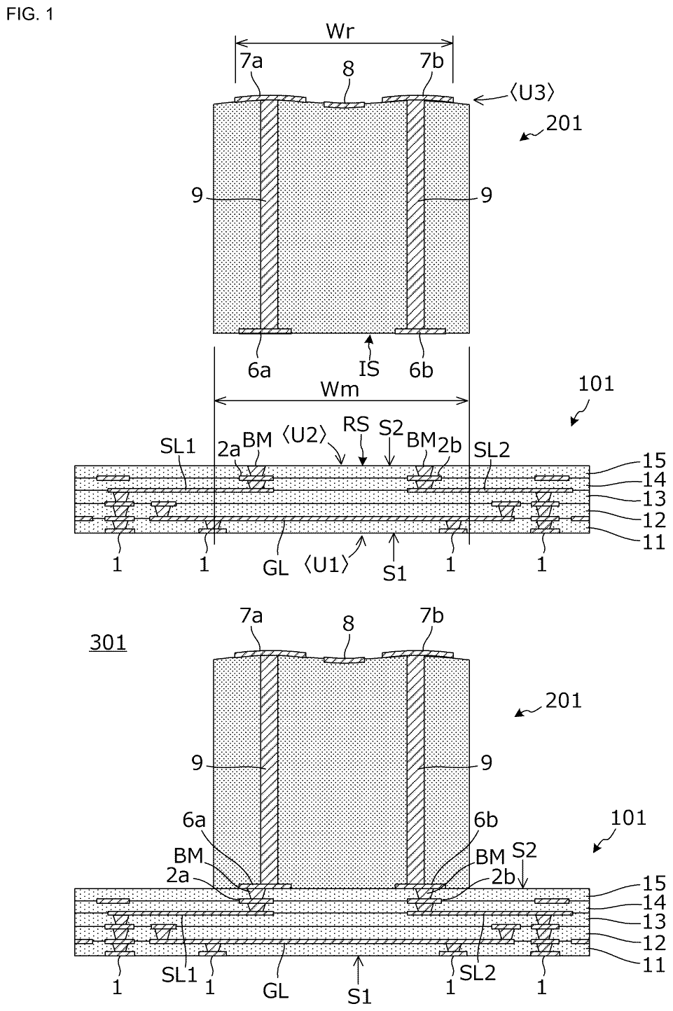

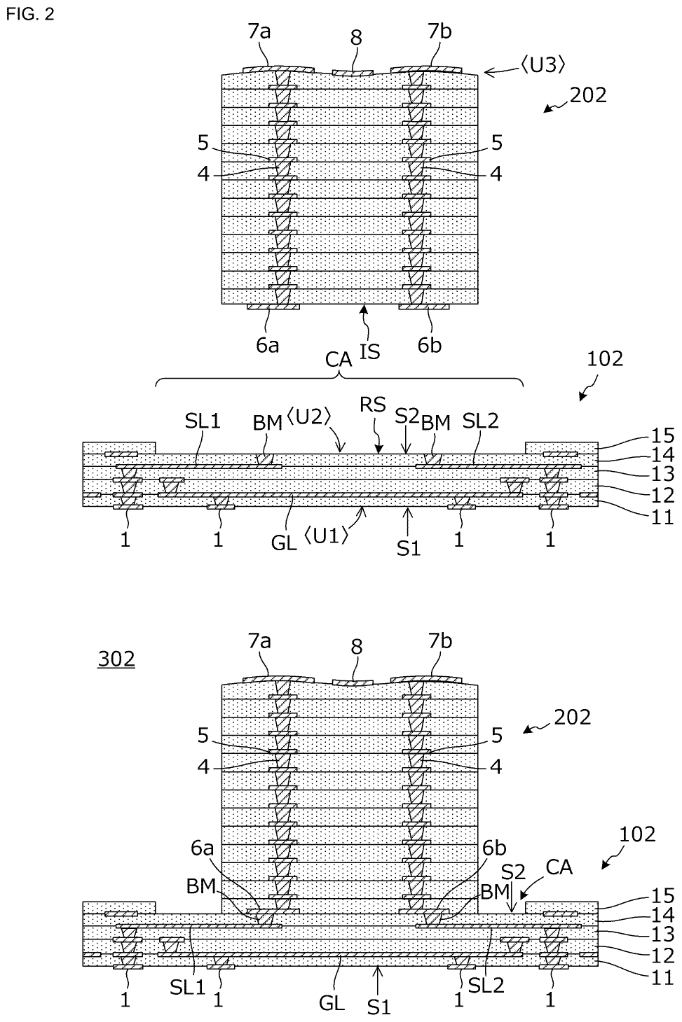

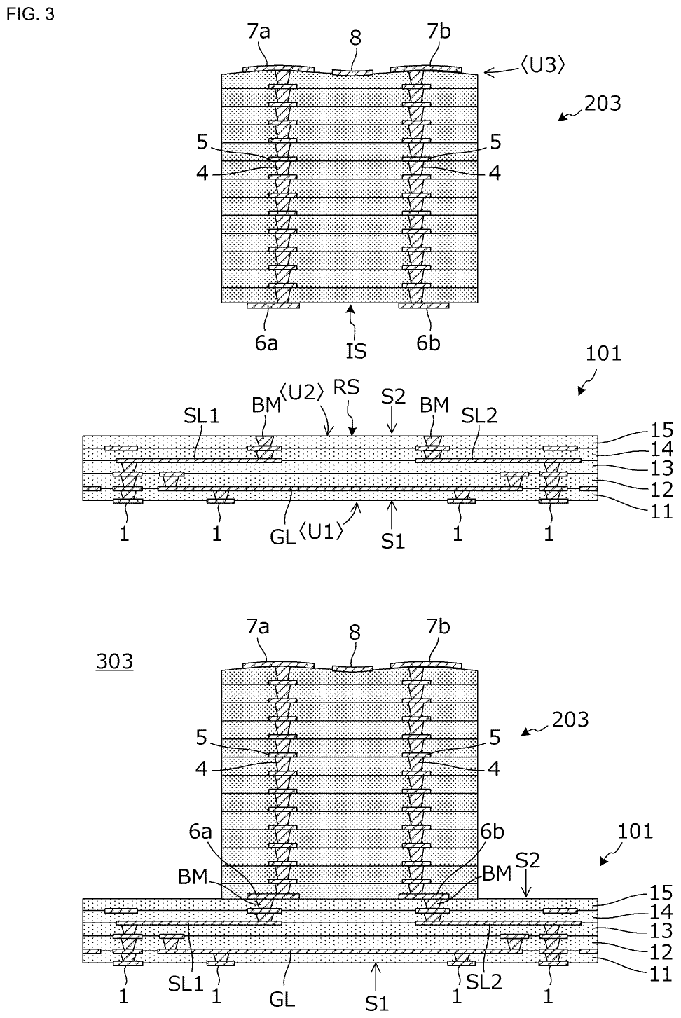

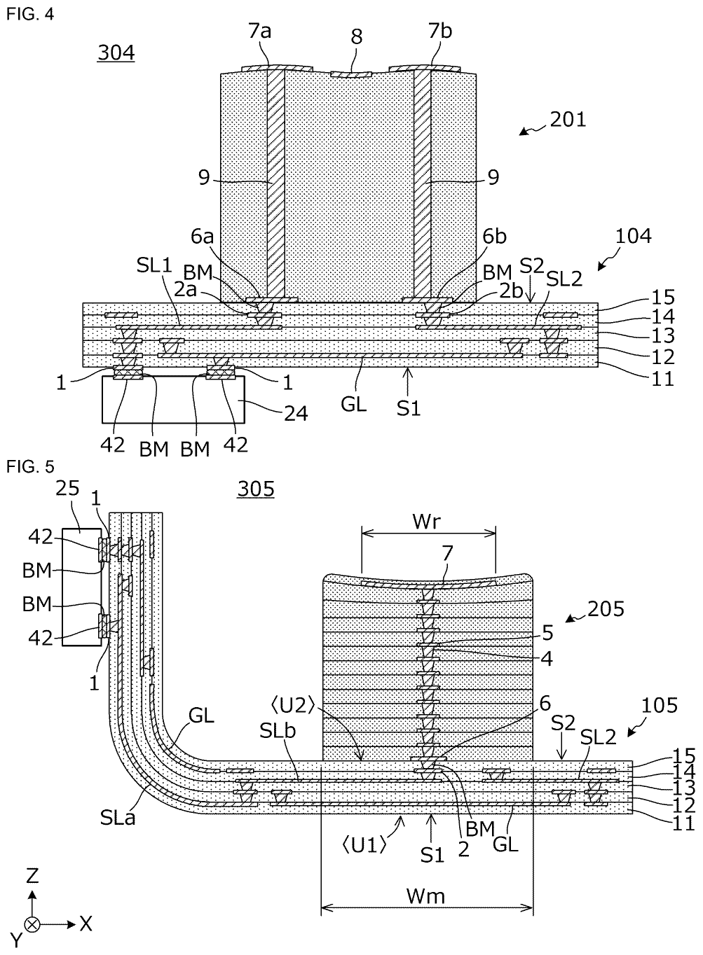

FIG. 4 is a sectional view of a module substrate 304 according to the fourth embodiment. The module substrate 304 includes a multilayer base plate 104, a mounting component 201, and an electronic component 24. The electronic component 24 is shown without crosshatching.

The multilayer base plate 104 includes a plurality of resin layers 11, 12, 13, 14, and 15, and a conductor layer and an interlayer connecting conductor that are provided at a predetermined one of the resin layers.

Opening portions of the resin layer 15 are coated with connecting conductors BM. Each connecting conductor BM is made of, for example, a heating molten metal, such as solder. Pad electrodes 2a and 2b provided at the multilayer base plate are formed at lower layers of the connecting conductors BM. In this example, the resin layers 11, 12, 13, and 14 constitute a multilayer body of thermoplastic resin sheets, one side of each having a Cu foil attached thereto.

Signal line conductor patterns SL1 and SL2 and a ground conductor layer GL are formed inside the multilayer base plate 104. Two microstrip type transmission lines are formed by the signal line conductor patterns SL1 and SL2, the ground conductor layer GL, and the resin layers provided between the signal line conductor patterns SL1 and SL2 and the ground conductor layer GL.

As shown in FIG. 4, the mounting component 201 is placed on a predetermined position on the multilayer base plate 104, and the entire structure is heated to a predetermined temperature and is compressed by a predetermined pressure. Therefore, the connecting conductors BM are melted and the pad electrodes 2a and 2b provided at the multilayer base plate are electrically connected to terminal electrodes 6a and 6b provided at the mounting component 201. In addition, an insulator surface IS of the mounting component 201 and the resin surface RS of the multilayer base plate 101 are directly joined to each other.

The structure of the mounting component 201 is the same as the structure of the mounting component 201 in the first embodiment.

Outer electrodes 1 are formed at a mounting surface (lower surface) of the multilayer base plate 104. Pad electrodes 42 provided at the component are formed at a mounting surface (upper surface) of the electronic component 24.

The pad electrodes 42 provided at the component are connected to the outer electrodes 1 of the multilayer base plate 104 via connecting conductors BM. Each connecting conductor BM is made of, for example, a heating molten metal, such as solder.

The electronic component 24 is, for example, an IC that amplifies a transmission signal in terms of electric power and supplies the electric power to an antenna, or an IC that amplifies a reception signal of the antenna.

According to the embodiment, since the mountability of the electronic component 24 with respect to the multilayer base plate 104 is high, it is possible to easily mount the electronic component 24 onto the multilayer base plate 104.

### Fifth Embodiment

In a fifth embodiment, a module substrate including a curved multilayer base plate is exemplified.

FIG. 5 is a sectional view of a module substrate 305 according to a fifth embodiment. The module substrate 305 includes a multilayer base plate 105 and a connector 25 that is mounted on the multilayer base plate 105. The connector 25 is shown without crosshatching.

An upper surface of a mounting component 205 has a relatively high maximum height roughness such that the mounting component 205 acts as a patch antenna or as a part of the patch antenna. In this example, a radiation electrode 7 is formed at or near the upper surface of the mounting component 205.

A terminal electrode 6 is formed at a mounting surface (lower surface) of the mounting component 205. A multilayer body including a plurality of conductor foils 5 and a plurality of interlayer connecting conductors 4 is formed between the terminal electrode 6 and the radiation electrode 7. In this way, by placing upon each other resin sheets each including the interlayer connecting conductor 4 and the conductor foil 5 that contacts the interlayer connecting conductor 4, a placement-direction conductor path is formed in the mounting component 205. By forming the placement-direction conductor path, an uneven portion is formed at a surface (upper surface) of the mounting component 205 on a side opposite to the mounting surface (lower surface) of the mounting component 205. The radiation electrode 7 is formed along the recessed portion.

Here, a maximum height roughness of a mounting-portion-opposite region of a first surface S1 of the multilayer base plate 105, in which a width Wm of the mounting-portion-opposite region is a standard length of a cross-sectional curve of the mounting-portion-opposite region, is denoted by Rz1, with the mounting-portion-opposite region being a region opposite to a mounting portion where the mounting component 205 is mounted.

A maximum height roughness of the mounting portion, where the mounting component 205 is mounted, of a second surface S2 of the multilayer base plate 105, in which a width Wm of the mounting portion is a standard length of a cross-sectional curve of the mounting portion, is denoted by Rz2.

A maximum height roughness of a surface of an insulator of the mounting component 205, in which a width Wr of a formation region of the radiation electrode 7 is a standard length of a cross-sectional curve of the insulator, is denoted by Rz3. Here, a “surface of an insulator” refers to a surface of an insulator that contacts an upper surface or a lower surface of the radiation electrode 7.

The relationship between the maximum height roughnesses Rz1, Rz2, and Rz3 is Rz1<Rz2<Rz3. In this way, the module substrate 305 has three surfaces having different roughnesses (unevennesses).

Signal line conductor patterns SLa and SLb and a ground conductor layer GL are formed inside the multilayer base plate 105. A microstrip type transmission line is formed by the signal line conductor patterns SLa and SLb, the ground conductor layer GL, and resin layers provided between the signal line conductor patterns SLa and SLb and the ground conductor layer GL.

A plurality of outer electrodes 1 are exposed at the first surface S1 of the multilayer base plate 105. A pad electrode 2 is formed at the second surface S2 of the multilayer base plate 105. A terminal electrode 6 provided at the mounting component 205 is joined to the pad electrode 2. A resin surface of the mounting component 205 is joined to the resin layers of the multilayer base plate 105.

The pad electrodes 42 provided at the component are connected to the outer electrodes 1 of the multilayer base plate 105 via connecting conductors BM. Each connecting conductor BM is made of, for example, a heating molten metal, such as solder.

In the example shown in FIG. 5, the multilayer base plate 105 is curved (bent) by 90 degrees in a direction of the mounting surface of the mounting component 205 along an X-Z plane.

The connector 25 is connected to a patch antenna that is formed by mounting the mounting component 205.

According to the embodiment, since the multilayer base plate 105 is flexible, it is possible to form the module substrate 305 with a predetermined shape in its entirety.

### Sixth Embodiment

In a sixth embodiment, a module substrate whose structure of a boundary portion between a multilayer base plate and a mounting component differs from that described thus far is described as an example.

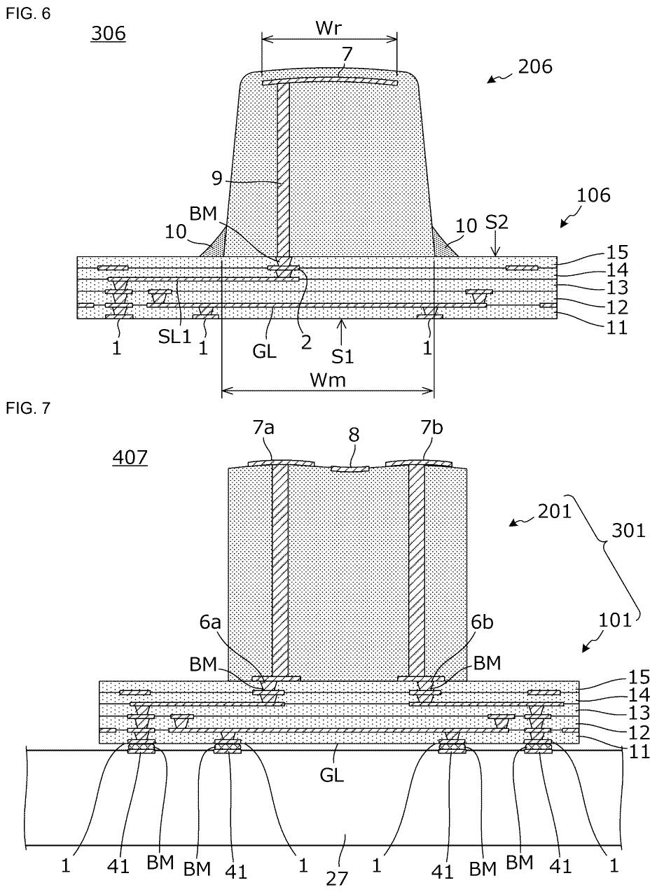

FIG. 6 is a sectional view of a module substrate 306 according to the sixth embodiment. The module substrate 306 includes a multilayer base plate 106 and a mounting component 206. The multilayer base plate 106 includes a plurality of resin layers 11, 12, 13, 14, and 15, and a conductor layer and an interlayer connecting conductor that are provided at a predetermined one of the resin layers. An opening portion of the resin layer 15 is coated with a connecting conductor BM. The connecting conductor BM is made of, for example, a heating molten metal, such as solder. A pad electrode 2 provided at the multilayer base plate is formed at a lower layer of the connecting conductor BM.

Radiation electrode 7 is formed at an upper surface or near the upper surface of the mounting component 206 such that the mounting component 206 acts as a patch antenna or as a part of the patch antenna. The radiation electrode 7 is disposed along the upper surface of the mounting component 206.

Here, a maximum height roughness of a mounting-portion-opposite region of a first surface S1 of the multilayer base plate 106, in which a width Wm of the mounting-portion-opposite region is a standard length of a cross-sectional curve of the mounting-portion-opposite region, is denoted by Rz1, with the mounting-portion-opposite region being a region opposite to a mounting portion where the mounting component 206 is disposed.

A maximum height roughness of the mounting portion, where the mounting component 206 is disposed, of a second surface S2 of the multilayer base plate 106, in which a width Wm of the mounting portion is a standard length of a cross-sectional curve of the mounting portion, is denoted by Rz2.

A maximum height roughness of a surface of an insulator of the mounting component 206, in which a width Wr of a formation region of the radiation electrode 7 is a standard length of a cross-sectional curve of the insulator, is denoted by Rz3. Here, a surface of an insulator “surface of an insulator” refers to a surface of an insulator that contacts an upper surface or a lower surface of the radiation electrode 7.

The relationship between the maximum height roughnesses Rz1, Rz2, and Rz3 is Rz1<Rz2<Rz3.

A boundary between the mounting component 206 and the multilayer base plate 106 (base portion of the mounting component 206) is covered by a resin member 10. By causing the resin member 10 to cover the second surface S2 of the multilayer base plate 106, a root portion of the mounting component 206 is held down at the multilayer base plate 106.

The resin member 10 is made of, for example, epoxy resin, and is applied and formed with the mounting component 206 being mounted on the multilayer base plate 106. It is desirable that the resin member 10 be a material having a Young's modulus that is higher than the Young's modulus of a material constituting the resin layers of the multilayer base plate 106.

The Young's modulus is determined by performing a nano indenter test under the standard of JIS Z 2255, ISO 14577. For example, by using a micro-nano indenter device manufactured by KLA Corporation, the Young's modulus is determined from load-displacement data.

Since the mounting portion where the mounting component 206 is mounted is rigid and the other portions are flexible, assuming an external force that tries to bend the module substrate 306 is applied to the module substrate 306, stress tends to concentrate at the root portion of the mounting component 206.

In the module substrate 306 of the embodiment, since the joining force between the multilayer base plate 106 and the mounting component 206 is high, an interface between the multilayer base plate 106 and the mounting component 206 is prevented from cracking or chipping. Since the rigidity of the mounting component 206 is high with respect to the multilayer base plate 106, deformation, such as tilting deformation, of the mounting component 206 can be suppressed. Therefore, a shift in an antenna radiating direction (directivity) can be suppressed.

Note that, although in FIG. 6, an example in which the resin member 10 is a member differing from the multilayer base plate 106 and the mounting component 206 is given, the shape of the resin member 10 may be formed from the multilayer base plate 106 or the mounting component 206. That is, after placing the mounting component 206 onto the multilayer base plate 106, pressure that pushes the mounting component 206 toward the multilayer base plate 106 is applied and heat is applied. Therefore, the mounting component 206 sinks into the multilayer base plate 106, the upper resin layer of the multilayer base plate 106 rises toward the root portion of the mounting component 206, and the raised portion is formed as the resin member 10. Alternatively, by the pressure and by the heating above, the root portion of the mounting component 206 is melted to form the resin member 10.

### Seventh Embodiment

In a seventh embodiment, an electronic device including a module substrate and another substrate is exemplified.

FIG. 7 is a sectional view of an electronic device 407 according to the seventh embodiment. The electronic device 407 includes another substrate 27, and a multilayer base plate 101 and a mounting component 201 that are mounted on the other substrate 27. The other substrate 27 is shown without crosshatching.

The structure of a module substrate 301 including the multilayer base plate 101 and the mounting component 201 is the same as that of the module substrate 301 shown in FIG. 1 in the first embodiment.

Outer electrodes 1 are formed at a mounting surface (lower surface) of the module substrate 301. Pad electrodes 41 provided at the other substrate are formed at a mounting surface (upper surface) of the other substrate 27.

The outer electrodes 1 provided at the multilayer base plate 101 are connected to the pad electrodes 41 provided at the other substrate via connecting conductors BM. Each connecting conductor BM is made of, for example, a heating molten metal, such as solder.

The other substrate 27 is, for example, a rigid glass epoxy resin substrate.

According to the embodiment, since the mountability of the multilayer base plate 101 with respect to a mounting surface of the highly flat other substrate 27 is high, it is possible to mount the module substrate 301 onto the other substrate 27 with high precision. For example, the multilayer base plate 101 where the outer electrodes 1 are dispersedly disposed can be easily mounted onto the other substrate 27.

### Eighth Embodiment

In an eighth embodiment, an electronic device including a housing is exemplified.

The electronic device according to the embodiment includes a module substrate according to any one of the first embodiment to the sixth embodiment, and a housing that accommodates the module substrate.

The housing that accommodates the module substrate has a size and a shape that can accommodate (incorporate) the module substrate.

Note that, in order not to lose antenna gain, at least a portion of the housing near the antenna is constituted by a nonconductive body or a nonmagnetic body.

Although, thus far, various embodiments according to the present disclosure have been described, the embodiments are all examples, and are not intended to limit the scope of the present disclosure. Various omissions, replacements, or changes may be made in the embodiments according to the present disclosure within a scope that does not depart from the spirit of the disclosure. Embodiments in which various omissions, replacements, or changes have been made are included within the scope of the present disclosure or the spirit of the present disclosure, and are included within a scope of the disclosure as described in the claims of the present application, and the scope of equivalents thereof.

For example, since the mounting component is a component that is provided in accordance with electrical characteristics required of an antenna, assuming it is important for the dielectric of the mounting component to have a high dielectric constant, a material having a dielectric constant that is higher than the dielectric constant of the resin layers of the multilayer base plate may be used. For example, a ceramic material having a high dielectric constant may be used. Therefore, it is possible to obtain a module substrate including an antenna that excels in electrical characteristics.

Although, in each of the embodiments, an example in which a protective film is formed on, for example, the multilayer base plate or the mounting component has not been given, a protective film may be formed on a predetermined portion of an outer surface or an entire outer surface of, for example, the multilayer base plate or the mounting component.

Although, in each of the embodiments, a microstrip transmission line is constituted by signal line conductor patterns SL and a ground conductor layer GL, the structure of the module substrate is not limited to one in which a transmission line is connected to the mounting component.

The multilayer base plate and the electronic device of the present disclosure may be provided in each of the following forms.

<1> A module substrate comprising:
a multilayer base plate that includes a plurality of resin layers and a conductor layer that is provided at a predetermined one of the plurality of resin layers; and
a mounting component that includes an insulator and a radiation electrode that is formed at the insulator, the mounting component being mounted on the multilayer base plate,
wherein the multilayer base plate has a first surface and a second surface, which have a relationship of being a front surface and a back surface,
wherein the multilayer base plate includes an outer electrode that is exposed at the first surface,
wherein the multilayer base plate includes a mounting portion at a part of the second surface of the multilayer base plate, the mounting portion being where the mounting component is mounted,
wherein the mounting component has a mounting surface that contacts the mounting portion of the multilayer base plate,
wherein the radiation electrode is formed at a surface away from the mounting surface or in a region along the surface,
wherein the resin layer at the mounting portion of the multilayer base plate and the insulator at the mounting surface of the mounting component are directly joined to each other, and
wherein assuming a maximum height roughness of a mounting-portion-opposite region of the first surface of the multilayer base plate, in which a width of the mounting-portion-opposite region is a standard length of a cross-sectional curve of the mounting-portion-opposite region, is denoted by Rz1, the mounting-portion-opposite region being a region opposite to the mounting portion,
assuming a maximum height roughness of the mounting portion of the second surface of the multilayer base plate, in which a width of the mounting portion is a standard length of a cross-sectional curve of the mounting portion, is denoted by Rz2, and
assuming a maximum height roughness of a surface of the insulator, in which a width of a formation region of the radiation electrode is a standard length of a cross-sectional curve of the insulator, is denoted by Rz3, a relationship between the maximum height roughnesses is Rz1<Rz2<Rz3.

<2> The module substrate according to <1>,
wherein a material of each of the resin layers of the multilayer base plate and a material of the insulator of the mounting component are of a same type.

<3> The module substrate according to <1>,
wherein a material of each of the resin layers of the multilayer base plate and a material of the insulator of the mounting component are of different types.

<4> The module substrate according to any one of <1> to <3>,
wherein each of the resin layers of the multilayer base plate is made of thermoplastic resin.

<5> The module substrate according to <4>,
wherein each of the resin layers of the multilayer base plate is made of liquid crystal polymer resin.

<6> The module substrate according to any one of <1> to <5>,
wherein the mounting component includes a terminal electrode, an interlayer connecting conductor whose main component is Cu or Ag is formed at the first surface of the multilayer base plate, and the terminal electrode of the mounting component is connected to the interlayer connecting conductor.

<7> The module substrate according to any one of <1> to <6>,
wherein a transmission line is formed in the multilayer base plate.

<8> The module substrate according to any one of <1> to <7>,
wherein the multilayer base plate includes a curved portion.

<9> The module substrate according to any one of <1> to <8>, comprising:
a component that is connected to the outer electrode and that is mounted on the multilayer base plate.

<10> The module substrate according to any one of <1> to <9>, comprising:
a resin member that covers a boundary between the mounting component and the multilayer base plate (root portion of the mounting component).

<11> An electronic device comprising:
the module substrate according to any one of <1> to <10>; and
another substrate on which the module substrate is mounted.

<12> An electronic device comprising:
the module substrate according to any one of <1> to <10>; and
a housing that accommodates the module substrate.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

What is claimed is:

1. A module substrate comprising:
a multilayer base plate that includes a plurality of resin layers and a conductor layer that is provided at a predetermined one of the plurality of resin layers; and
a mounting component that includes an insulator and a radiation electrode that is formed at the insulator, the mounting component being mounted on the multilayer base plate,
wherein the multilayer base plate has a first surface and a second surface, which have a relationship of being a front surface and a back surface,
wherein the multilayer base plate includes an outer electrode that is exposed at the first surface,
wherein the multilayer base plate includes a mounting portion at a part of the second surface of the multilayer base plate, the mounting portion being where the mounting component is mounted,
wherein the mounting component has a mounting surface that contacts the mounting portion of the multilayer base plate,
wherein the radiation electrode is formed at a surface away from the mounting surface or in a region along the surface,
wherein the resin layer at the mounting portion of the multilayer base plate and the insulator at the mounting surface of the mounting component are directly joined to each other, and
wherein based on a maximum height roughness of a mounting-portion-opposite region of the first surface of the multilayer base plate, in which a width of the mounting-portion-opposite region is a standard length of a cross-sectional curve of the mounting-portion-opposite region, is denoted by Rz1, the mounting-portion-opposite region being a region opposite to the mounting portion,
based on a maximum height roughness of the mounting portion of the second surface of the multilayer base plate, in which a width of the mounting portion is a standard length of a cross-sectional curve of the mounting portion, is denoted by Rz2, and
based on a maximum height roughness of a surface of the insulator, in which a width of a formation region of the radiation electrode is a standard length of a cross-sectional curve of the insulator, is denoted by Rz3,
a relationship between the maximum height roughnesses is Rz1<Rz2<Rz3.

2. The module substrate according to claim 1,
wherein a material of each of the resin layers of the multilayer base plate and a material of the insulator of the mounting component are of a same type.

3. The module substrate according to claim 1,
wherein a material of each of the resin layers of the multilayer base plate and a material of the insulator of the mounting component are of different types.

4. The module substrate according to claim 3,
wherein each of the resin layers of the multilayer base plate is made of thermoplastic resin.

5. The module substrate according to claim 4,
wherein each of the resin layers of the multilayer base plate is made of liquid crystal polymer resin.

6. The module substrate according to claim 3,
wherein the mounting component includes a terminal electrode, an interlayer connecting conductor whose main component is Cu or Ag is formed at the first surface of the multilayer base plate, and the terminal electrode of the mounting component is connected to the interlayer connecting conductor.

7. The module substrate according to claim 3,
wherein a transmission line is formed in the multilayer base plate.

8. The module substrate according to claim 3,
wherein the multilayer base plate includes a curved portion.

9. The module substrate according to claim 3, comprising:
a component that is connected to the outer electrode and that is mounted on the multilayer base plate.

10. The module substrate according to claim 3, comprising:
a resin member that covers a boundary between the mounting component and the multilayer base plate.

11. An electronic device comprising:
the module substrate according to claim 1; and
another substrate on which the module substrate is mounted.

12. An electronic device comprising:
the module substrate according to claim 1; and
a housing that accommodates the module substrate.

13. The module substrate according to claim 1,
wherein each of the resin layers of the multilayer base plate is made of thermoplastic resin.

14. The module substrate according to claim 13,
wherein each of the resin layers of the multilayer base plate is made of liquid crystal polymer resin.

15. The module substrate according to claim 1,
wherein the mounting component includes a terminal electrode, an interlayer connecting conductor whose main component is Cu or Ag is formed at the first surface of the multilayer base plate, and the terminal electrode of the mounting component is connected to the interlayer connecting conductor.

16. The module substrate according to claim 1,
wherein a transmission line is formed in the multilayer base plate.

17. The module substrate according to claim 1,
wherein the multilayer base plate includes a curved portion.

18. The module substrate according to claim 1, comprising:
a component that is connected to the outer electrode and that is mounted on the multilayer base plate.

19. The module substrate according to claim 1, comprising:
a resin member that covers a boundary between the mounting component and the multilayer base plate.

20. The module substrate according to claim 2,
wherein each of the resin layers of the multilayer base plate is made of thermoplastic resin, and
wherein each of the resin layers of the multilayer base plate is made of liquid crystal polymer resin.
